(19) United States
(12) Patent Application Publication
(10) Pub. No.: US 2010/0052095 A1
(43) Pub. Date: Mar. 4, 2010

(54) INDUCTOR FOR SEMICONDUCTOR DEVICE AND METHOD OF FABRICATING THE SAME

(76) Inventor: Su-Tae Kim, Jinan-gun (KR)

Correspondence Address: SHERR & VAUGHN, PLLC, 620 HERNDON PARKWAY, SUITE 320, HERNDON, VA, 20170, US

(21) Appl. No.: 12/199,443

(22) Filed: Aug. 27, 2008

(30) Foreign Application Priority Data
Aug. 27, 2008 (KR) 10-2007-0086196

(51) Int. Cl. H01L 29/00; H01L 21/20

(52) U.S. Cl. 257/531; 438/381; 257/E29.001; 257/E21.09

(57) ABSTRACT

An inductor for semiconductor devices and a method of fabricating the same are disclosed. Through an improved electrical connection between a metal wiring and an inductor line, an improved Q-index and minimized energy loss in a substrate can be accomplished, and a parasitic capacitance can be minimized. For this, the inductor which may include a substrate and an insulating layer formed over the substrate and containing a metal wiring therein. A metal pad may be formed over the insulating layer. An inductor line may be formed over the insulating layer and connected to the metal pad. A pad contact, a metal layer and a via contact may be sequentially stacked within the insulating layer between the metal wiring and the metal pad.

The present application claims priority under 35 U.S.C. 119 to Korean Patent Application No. 10-2007-0086196 (filed on Aug. 27, 2008), which is hereby incorporated by reference in its entirety.

### BACKGROUND

With developments in micro-processing technologies, complementary Metal-Oxide Semiconductors (CMOS) have good high-frequency characteristics. This allows fabrication of low-price chips using semiconductor process technologies. In particular, a System On Chip (SOC) technology enables integration of digital parts operating at a medium frequency band of a system. Thus, SOC has received attention as the most appropriate technology for fabrication of a single chip.

The main constituent components of RF-CMOS or Bipolar/BiCMOS devices include RF-MOSFETs, inductors, varactors, MIM capacitors, and resistors. In particular, an inductor is a single device occupying the largest area of a chip and is very limited in its high-frequency characteristics because of parasitic capacitance and resistance inherent in the interior configuration and constituent materials thereof.

FIG. 1 is a perspective sectional view illustrating the configuration of an inductor 30 for semiconductor devices according to the related art. The related art inductor 30 includes an inductor line 31, a metal pad 32, an insulating layer 20, and a plurality of metal wirings 33 and 40 formed in the insulating layer 20. The insulating layer 20 contains a plurality of via contacts 34, which electrically connect the metal wirings 33 and 40 to each other, or electrically connect the metal wirings 33 and 40 to the metal pad 32. With the configuration described above, electric connection between the lowermost metal wiring 40 and the top metal pad 32 may be accomplished.

A Q-index (Quality factor) of an inductor is proportional to an inductance value and is inversely proportional to a resistance component. Accordingly, the Q-index can be improved when a series resistance component is reduced via the connection of the plurality of metal wirings 33 and 40 and the via contacts 34.

However, the metal wirings 33 and 40 formed in the insulating layer 20 take the form of thin plates, and are arranged close to the substrate 10 as well as the metal pad 32. This causes energy loss in the substrate 10. Further, the metal wirings 33 and 40 and the via contacts 34 have been stacked one above another in multiple layers which necessitates a great number of processes. This is detrimental to production efficiency and costs.

Furthermore, parasitic capacitances occur between the metal pad 32 and the metal wirings 33 and 40, between the inductor line 31 and the metal wirings 33 and 40, between the respective neighboring metal wirings 33 and 40, and between the substrate 10 and all the layers stacked over the substrate 10, causing a lowered Self-Resonant Frequency (SRF). Overall, the multi-stack configuration described above, with the metal wirings 33 and 40 and the via contacts 34, complicates semiconductor device design.

### SUMMARY

Embodiments relate to semiconductor technologies, and more particularly, to an inductor for semiconductor devices and a method of fabricating the same. Embodiments relate to an inductor for semiconductor devices, which has an improved electrical connection between a metal wiring and an inductor line, thereby achieving an improved Q-index, and a method of fabricating the inductor. Embodiments relate to an inductor for semiconductor devices, which can minimize energy loss in a substrate, thereby restricting occurrence of a parasitic capacitance, and a method of fabricating the inductor.

Embodiments relate to an inductor for semiconductor devices which may include a substrate and an insulating layer formed over the substrate and containing a metal wiring therein. A metal pad may be formed over the insulating layer. An inductor line may be formed over the insulating layer and connected to the metal pad. A pad contact, a metal layer and a via contact may be sequentially stacked within the insulating layer between the metal wiring and the metal pad. The pad contact may be connected to a lower surface of the metal pad. The metal layer may be connected to a lower surface of the pad contact. The via contact may connect the metal layer and the metal wiring to each other.

Embodiments relate to a method of fabricating an inductor for semiconductor devices including: forming a first insulating layer, containing a metal wiring and a via contact connected to the metal wiring, over a substrate; forming a second insulating layer over the first insulating layer; forming a trench in the second insulating layer; sequentially forming a metal layer, connected to the via contact, and a pad contact over the metal layer within the trench; and forming a metal pad over the pad contact and forming an inductor line, connected to the metal pad, over the second insulating layer.

Embodiments relate to a method of fabricating an inductor for semiconductor devices including: forming a first insulating layer, containing a metal wiring and a via contact connected to the metal wiring, over a substrate; forming a second insulating layer over the first insulating layer; forming a first trench in the second insulating layer; forming a metal layer, connected to the via contact, in the first trench; forming a third insulating layer over the second insulating layer; forming a second trench to expose the metal layer over the third insulating layer; forming a pad contact, connected to the metal layer, in the second trench; and forming a metal pad over the pad contact and forming an inductor line, connected to the metal pad, over the third insulating layer.

### DRAWINGS

FIG. 1 is a perspective sectional view illustrating the configuration of an inductor for semiconductor devices according to the related art.

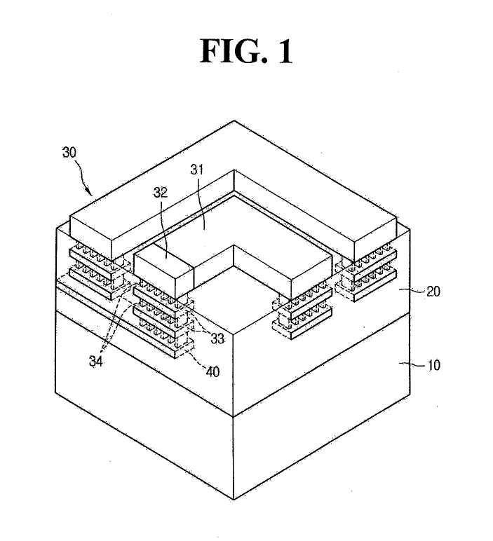

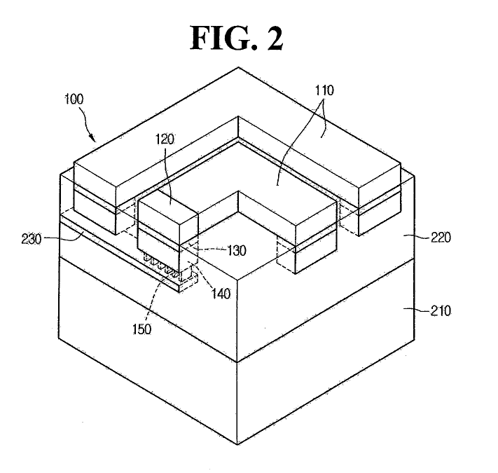

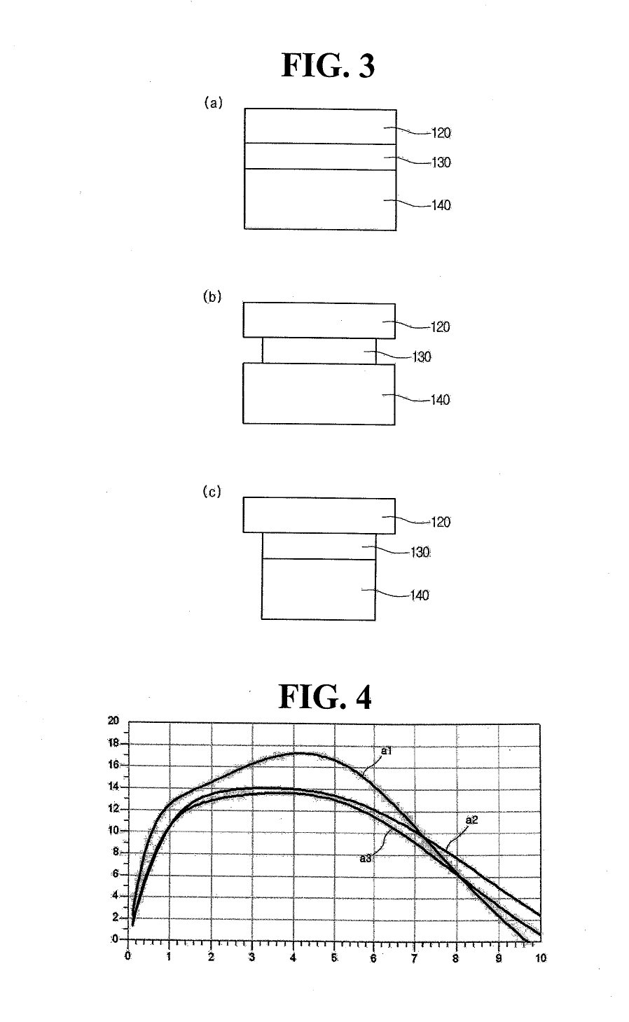

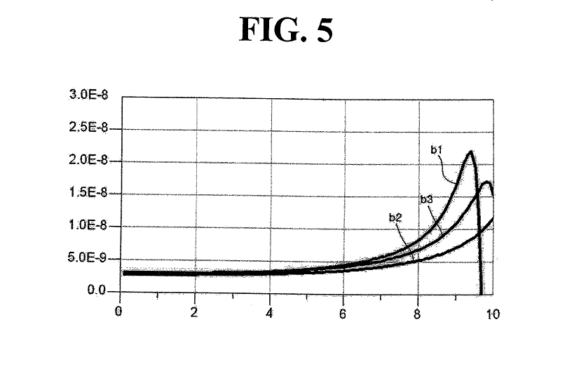

Example FIG. 2 is a perspective sectional view illustrating the configuration of an inductor for semiconductor devices according to embodiments.

Example FIGS. 3A to 3C are side sectional views illustrating different configurations of the inductor according to embodiments.

Example FIG. 4 is a graph illustrating a Q-index of the inductor according to embodiments.

Example FIG. 5 is a graph illustrating an inductance value of the inductor according to embodiments.

### DESCRIPTION

Now, an inductor for semiconductor devices and a method of fabricating the same according to embodiments will be described in detail with reference to the accompanying drawings. Example FIG. 2 is a perspective sectional view illustrating the configuration of an inductor 100 for semiconductor devices according to embodiments. Referring to example FIG. 2, the inductor 100 may include an inductor line 110, a metal pad 120, a pad contact 130, and a metal layer 140. Here, the metal layer 140 may be formed of Ultra Thick Metal (UTM). The inductor 100 may be manufactured together with semiconductor devices, such as CMOS devices, NMOS devices, PMOS devices, and the like.

The inductor 100 may include an insulating layer 220 formed over a substrate 210. The insulating layer 220 may contain a metal wiring 230. The insulating layer 220 may be formed of Tetra Ortho Silicate Glass (TEOS) or oxide-based materials. The metal wiring 230 functions as a medium to electrically connect the inductor line 110, arranged over the upper side of the insulating layer 220, to another structure, for example, a semiconductor device. A semiconductor device may be formed in an active area over the insulating layer 220.

The insulating layer 220 containing the metal wiring 230 may also contain a via contact 150 connected to the metal wiring 230, the metal layer 140 connected to the via contact 150, and the pad contact 130 connected to the metal layer 140, which may be respectively sequentially formed in the insulating layer 220. The metal pad 120 and the inductor line 110 may be formed over the insulating layer 220, such that the metal pad 120 and the inductor line 110 are connected to each other. The metal pad 120 may also be connected to the pad contact 130 formed in the insulating layer 220.

In the multi-stack configuration according to embodiments described above, the inductor line 110 and the metal pad 120 may constitute an uppermost layer, and the insulating layer 220 (in which the pad contact 130, the metal layer 140, the via contact 150, and the metal wiring 230 may be formed) may be provided below the inductor line 110 and the metal pad 120. More particularly, the pad contact 130, the metal layer 140 and the via contact 150 may be stacked between the metal wiring 230 and the metal pad 120, such that the pad contact 130 is connected to a lower surface of the metal pad 120, the metal layer 140 is connected to a lower surface of the pad contact 130, and the via contact 150 connects the metal layer 140 to the metal wiring 230.

Although example FIG. 2 illustrates a single insulating layer 220, in alternative embodiments, the insulating layer may be divided into multiple insulating layers stacked one above another, according to etching processes of forming the metal wiring 230, the via contact 150, the metal layer 140, and the pad contact 130, respectively.

Alternative embodiments using the multiple insulating layers 220 will be described with reference to example FIGS. 3A to 3C. The metal layer 140, which may be formed of UTM, takes the form of a thick single metal layer between the pad contact 130 and the via contact 150 to electrically connect the metal wiring 230 and the metal pad 120 to each other. The metal layer 140 may be made of metal such as copper.

The UTM metal layer 140 has several advantages. The UTM metal layer 140 can reduce a series resistance component. The UTM metal layer 140 can improve a Q-index. The UTM metal layer 140 can also improve an inductance value in a high-frequency region in consideration of RF characteristics. Further, the metal pad 120 can be sufficiently spaced apart from the substrate 210 via the UTM metal layer 140 and therefore, energy loss in the substrate 210 can be prevented.

In addition to forming the UTM metal layer 140, in embodiments, the via contact 150 may be formed to have a large width. A trench for formation of the metal layer 140 and the via contact 150 may have a differentiated configuration from that for formation of general metal wirings as follows. First, the metal layer 140 and the via contact 150 may have a relatively larger line width and depth than general metal wirings. Second, the insulating layer 220 may have a larger thickness due to the larger line width and depth of the metal layer 140 and the via contact 150. Third, the trench for formation of the metal layer 140 and the via contact 150 may be formed via an etching process and thus, a photoresist pattern used in the etching process may have a larger thickness than the metal layer 140.

For example, according to design rules, the metal layer 140 may have a line width of approximately 2.9 μm or more and a depth of approximately 4.5 μm or more. Accordingly, the trench for formation of the metal layer 140 may be formed to have a larger line width by approximately 2 μm or more and a larger depth by approximately 2.5 μm or more than that for formation of related metal wirings provided in an insulating layer.

As shown in example FIG. 2, the pad contact 130 is stacked above the metal pad 140, and may be formed of aluminum in the same manner as the metal pad 120, rather than being made of tungsten. With the configuration described above, the pad contact 130 can achieve a remarkable reduction in resistance. As a result of forming the pad contact 130 of the same metal as that of the metal pad 120, the pad contact 130 can be formed over the metal layer 140 via a deposition process without using additional etching/burying processes. The metal pad 120 may be formed over the pad contact 130, and may be connected to the inductor line 110.

As described above, after forming the single trench, the metal layer 140 and the pad contact 130 are sequentially stacked in the trench such that the metal layer 140 and the pad contact 130 can be directly connected to the metal pad 120. This can reduce a parasitic capacitance and restrict degradation of the SRF.

The inductor line 10 may be formed over the insulating layer 220, far from the substrate 210, in order to minimize energy loss of the substrate 210. For example, the inductor line 110 may take the form of a metal line bent plural times, and more particularly, may have a planar spiral geometric form. When using a 0.13 μm RF-CMOS semiconductor process, the inductor line 110 may be formed of a copper line having a line width of approximately 3.3 μm.

The inductor line 110 may be connected to the metal pad 120, for electric connection with another passive device in the semiconductor device and an exterior circuit. The metal pad 120 may have a rectangular form. Wire-bonding the metal pad 120 with a circuit using, for example, ultrasonic bonding, can minimize a bonding region. The metal pad 120 may be formed of aluminum having superior oxidation resistance.

Example FIGS. 3A to 3C are side sectional views illustrating different configurations of the inductor for semiconductor devices according to embodiments. Referring to example FIGS. 3A to 3C in which different three configurations of the inductor for semiconductor devices are illustrated, the metal layer 140, the pad contact 130 and the metal pad 120 are shown in enlarged view.

Example FIG. 3A illustrates the configuration as described with reference to example FIG. 2. In example FIG. 3A, the metal layer 140, the pad contact 130, and the metal pad 120 have the same width. Accordingly, after forming a single trench in the insulating layer 220, via deposition processes, the metal layer 140 and the pad contact 130 are sequentially deposited in the trench, and the metal pad 120 is formed over the pad contact 130. For reference, the insulating layer 220 may be divided into multiple layers. For example, the insulating layer 220 may include a first insulating layer in which the metal wiring 230 is formed, a second insulating layer in which the via contact 150 is formed, a third insulating layer in which the metal layer 140 is formed, and a fourth insulating layer in which the pad contact 130 is formed.

Alternatively, the insulating layer 220 may include a first insulating layer in which the metal wiring 230 and the via contact 150 connected to the metal wiring 230 are formed, a second insulating layer in which the metal layer 140 is formed, and a third insulating layer in which the pad contact 130 is formed. In the case of the multi-layered insulating layer 220, the metal wiring 230, the via contact 150, the metal layer 140, and the pad contact 130 may be formed in the respective insulating layers via etching processes.

The technical idea of embodiments is deeply associated with the configurations of the metal layer 140, the pad contact 130, and the metal pad 120 and therefore, formation of other metal configurations and the insulating layer 220 will not be described in detail herein.

Referring to example FIG. 3B illustrating a configuration of an inductor according to embodiments, a metal pad 120 and a metal layer 140 may have the same width, and a pad contact 130 may have a smaller width than that of the metal pad 120 and the metal layer 140. Embodiments as shown in FIG. 3B may be manufactured according to the following processes.

First and second insulating layers, in which a metal wiring 230 and a via contact 150 are formed, may be stacked over the substrate 210. A first trench may be formed in the second insulating layer. Copper may be buried in the first trench to form metal layer 140 connected to via contact 150 in the first trench, and then, a planarizing process may be performed. Thereafter, a third insulating layer may be stacked over the second insulating layer. A second trench, which has a smaller width than that of the first trench, may be formed in the third insulating layer, to expose the metal layer 140 to the outside. Aluminum may be buried in the second trench, to form the pad contact 130 connected to the metal layer 140 in the second trench, and then, a planarizing process may be performed. After an additional insulating layer is stacked over the third insulating layer, a photoresist process, an etching process, an aluminum burying process, and a photoresist/insulating layer removal process may be performed, forming the metal pad 120 over the pad contact 130.

Referring to example FIG. 3C illustrating the configuration of the inductor according to embodiments, the metal layer 140 and the pad contact 130 may have the same width, and the metal pad 120 may have a larger width than that of the metal layer 140 and the pad contact 130. In embodiments, the following processes may be performed.

A first insulating layer, in which a metal wiring 230 and a via contact 150 may be formed, may be stacked over a substrate 210. A second insulating layer may be stacked over the first insulating layer. A trench may be formed in the second insulating layer.

Copper may be deposited in a lower region of the trench, to form a metal layer 140 connected to the via contact 150 in the trench. Subsequently, aluminum may be deposited in an upper region of the trench above the metal layer 140, to form a pad contact 130, and then a planarizing process may be performed.

After an additional insulating layer is stacked over the second insulating layer, a photoresist process, an etching process, an aluminum burying process, and a photoresist/insulating layer removal process may be performed, forming a metal pad 120 over the pad contact 130 such that the metal pad 120 has a larger width than that of the pad contact 130.

In embodiments described above, the pad contact 130 may have a width approximately 10% less than that of the metal pad 120 and the metal layer 140. In embodiments formed in accordance with FIG. 3C, the metal layer 140 and the pad contact 130 have the same width approximately 10% less than that of the metal pad 120.

Example FIG. 4 is a graph illustrating a Q-index of the inductor for semiconductor devices according to embodiments. In example FIG. 4, the abscissa represents a frequency band, and the ordinate represents a Q-index. It can be appreciated from example FIG. 4 that the inductor according to embodiments has a better Q-index a1 than a reference value a2 within a frequency band up to approximately 7.2 GHz. On the other hand, the related art inductor has a Q-index a3 slightly less than the reference value a2.

Example FIG. 5 is a graph illustrating an inductance value of the inductor for semiconductor devices according to embodiments. In example FIG. 5, the abscissa represents a frequency band, and the ordinate represents an inductance value. It can be appreciated from example FIG. 5 that the inductor according to the embodiments has a better inductance value b1 than a reference inductance value b2 and a related art inductance value b3 throughout an entire frequency band. In particular, measurements showed that inductors according to embodiments have a remarkably improved inductance value in a high frequency band of approximately 5 GHz to 9 GHz. For reference, the graphs shown in example FIGS. 4 and 5 illustrate the Q-index and the inductance value measured using High Frequency Structure Simulator (HFSS) equipment.

As apparent from the above description, embodiments have the following effects. A reduced series resistance component between a metal pad, an inductor line, and a metal wiring can improve a Q-index of an inductor. Using a thick metal layer can minimize energy loss of a substrate and restrict occurrence of a parasitic capacitance, achieving a maximized SRF. An inductance value in a high frequency region can be increased, and additional processes, such as a photoresist process, etching process and masking process, can be simplified. This has the effect of improving production efficiency and reducing fabrication costs. A simplified electric connection configuration between the metal pad and the metal wiring has the effect of facilitating design of a semiconductor device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a substrate;
an insulating layer formed over the substrate and containing a metal wiring therein;
a metal pad formed over the insulating layer;
an inductor line formed over the insulating layer and connected to the metal pad; and
a pad contact, a metal layer and a via contact sequentially stacked within the insulating layer between the metal wiring and the metal pad.

2. The apparatus of claim 1, wherein:
the pad contact is connected to a lower surface of the metal pad;
the metal layer is connected to a lower surface of the pad contact; and
the via contact connects the metal layer and the metal wiring to each other.

3. The apparatus of claim 1, wherein the metal layer is an ultra thick metal layer.

4. The apparatus of claim 1, wherein the metal pad and the pad contact are made of substantially the same metal.

5. The apparatus of claim 1, wherein the metal pad and the pad contact are made of aluminum.

6. The apparatus of claim 1, wherein the metal pad, the pad contact, and the metal layer have substantially the same width.

7. The apparatus of claim 1, wherein:
the metal pad and the metal layer have the substantially the same width; and
the pad contact has a smaller width than a width of the metal pad and the metal layer.

8. The apparatus of claim 1, wherein the pad contact and the metal layer have the same width smaller than a width of the metal pad.

9. A method comprising:
forming a first insulating layer, containing a metal wiring and a via contact connected to the metal wiring, over a substrate;
forming a second insulating layer over the first insulating layer;
forming a trench in the second insulating layer;
sequentially forming a metal layer, connected to the via contact, and a pad contact over the metal layer within the trench; and
forming a metal pad over the pad contact and forming an inductor line, connected to the metal pad, over the second insulating layer.

10. The method of claim 9, wherein the metal pad and the pad contact have the same width.

11. The method of claim 9, wherein the metal pad has a larger width than a width of the pad contact.

12. The method of claim 9, wherein the metal layer is an ultra thick metal layer.

13. A method comprising:
forming a first insulating layer, containing a metal wiring and a via contact connected to the metal wiring, over a substrate;
forming a second insulating layer over the first insulating layer;
forming a first trench in the second insulating layer;
forming a metal layer, connected to the via contact, in the first trench;
forming a third insulating layer over the second insulating layer;
forming a second trench to expose the metal layer over the third insulating layer;
forming a pad contact, connected to the metal layer, in the second trench; and
forming a metal pad over the pad contact and forming an inductor line, connected to the metal pad, over the third insulating layer.

14. The method of claim 13, wherein the metal pad and the metal layer have substantially the same width.

15. The method of claim 13, wherein the second trench has a substantially smaller width than a width of the first trench.

16. The method of claim 13, wherein the metal layer is an ultra thick metal layer.

17. The method of claim 13, wherein a planarizing process is performed after forming the metal layer, connected to the via contact, in the first trench.

18. The method of claim 13, wherein a planarizing process is performed after forming the pad contact, connected to the metal layer, in the second trench.

19. The method of claim 16, wherein the metal layer is formed of copper.

20. The method of claim 19, wherein the pad contact is formed of aluminum.
